(19) United States
(12) Patent Application Publication
(10) Pub. No.: US 2010/0026372 A1
(43) Pub. Date: Feb. 4, 2010

(54) Power switch for transmitting a power source of low voltage between regular mode and deep-power-down mode

(76) Inventors: Yen-An Chang, Miaoli County (TW); Der-Min Yuan, Taipei County (TW)

Correspondence Address: NORTH AMERICA INTELLECTUAL PROPERTY CORPORATION, P.O. BOX 506, MERRIFIELD, VA, 22116, US

(21) Appl. No.: 12/353,247

(22) Filed: Jan. 13, 2009

(30) Foreign Application Priority Data
Jul. 30, 2008 (TW) 097128757

(51) Int. Cl. H03K 17/687

(52) U.S. Cl. 327/434; 327/427; 327/544

(57) ABSTRACT

A low-voltage power switch includes a gate-controlled circuit and a switch. The gate-controlled circuit generates a control voltage lower than the voltage of ground according to a control signal. The switch includes a first end, a second end, and a control end. The first end of the switch is coupled to a power supply of a low voltage, the control end of the switch is coupled to the gate-controlled circuit for receiving the gate-controlled signal, and the second end of the switch couples the first end of the switch when the switch receives the gate-controlled signal for outputting the power supply of the low voltage.

### BACKGROUND OF THE INVENTION

1. Field of the Invention

The present invention relates to a power switch for a power source of low voltage, and more particularly, to a power switch for transmitting a power source of low voltage between regular mode and deep-power-down mode.

2. Description of the Prior Art

In electronic devices applied with power sources of low voltage, generally a main power source V_{DD} (providing a voltage V_{DD}) and an internal chip power source V_{CC} (providing a voltage V_{CC}) are provided. Under the condition that the power consumption is not critical, normally the main power source V_{DD} is directly connected to the internal chip power source V_{CC}. That is, the voltage V_{DD} equals the voltage V_{CC}, thereby keeping the internal chips having the maximum operating voltage and operating at the fastest speed.

However, for portable electronic devices such as cellular phones, the power consumption is critical, and therefore the internal components such as memories and control chips have to be able to function under low power condition. Consequently deep-power-down mode is utilized for reducing power consumption of the portable electronic devices. The deep-power-down mode means that under the condition that the portable electronic device is not turned off, the internal chip power source is turned off. More particularly, in deep-power-down mode, the main power source V_{DD} is still turned on and keeps providing the voltage V_{DD} and the internal chip power source V_{CC} is turned off to stop providing the voltage V_{CC}. In this way, the power consumption of the internal chips of the portable electronic device can be reduced when the portable electronic device is in the sleep mode.

Please refer to FIG. 1 and FIG. 2. FIG. 1 is a diagram illustrating a conventional power switch Q_{P1} for achieving the deep-power-down mode. FIG. 2 is a timing diagram illustrating the control signal for the conventional power switch Q_{P1}. As shown in FIG. 1, the power switch Q_{P1} is a P channel Metal Oxide Semiconductor (PMOS) transistor. The first end (source) of the power switch Q_{P1} is coupled to the main power source V_{DD}, the control end (gate) of the power switch Q_{P1} receives a gate control signal S_{GP}, and the second end (drain) of the power switch Q_{P1} outputs the power source V_{CC} according to the gate control signal S_{GP}. The power source V_{DD} can be the main power source of the portable electronic device, and the power source V_{CC} can be the internal chip power source for providing voltage V_{CC} to the internal chips of the portable electronic device. As shown in FIG. 2, the voltage of the gate control signal S_{GP} falls between the voltages V_{DD} and V_{SS} (ground). Generally, when the power switch Q_{P1} is to be turned on (the first end of the power switch Q_{P1} is coupled to the second of the power switch Q_{P1} for outputting the voltage V_{CC}), the voltage of the gate control signal S_{GP} has to fall to the voltage V_{SS}; on the other hand, when the power switch Q_{P1} is to be turned off (the first end of the power switch Q_{P1} is not coupled to the second of the power switch Q_{P1} and consequently the voltage V_{CC} is not outputted), the voltage of the gate control signal S_{GP} has to rise to the voltage V_{DD}. In this way, the internal chip power source can be switched between the regular mode and the deep-power-down mode of the portable electronic device for meeting the requirement of the high speed in the regular mode and the power saving in the deep-power-down mode.

Generally, when the main power source V_{DD} is high enough, the voltage drop between the voltages V_{DD} and V_{CC} is ignorable. However, when the main power source V_{DD} provides a lower voltage (such as 1.8 volts or lower than that), the voltage drop between the voltages V_{DD} and V_{CC} cannot be ignorable. Since the gate control signal S_{GP} cannot have the power switch Q_{P1} turn on completely, causing considerable resistance on the power switch Q_{P1}, the voltage V_{CC} would be much lower than the voltage V_{DD} and it possibly effects the normal operations of the chips.

### SUMMARY OF THE INVENTION

The present invention provides a power switch for transmitting a power source providing a low voltage between regular mode and deep-power-down mode. The power switch comprises a first gate control circuit and a first switch. The first gate control circuit is disposed for generating a first gate control signal according to a control signal. Voltage of the first gate control signal is lower than ground. The first switch comprises a first end, coupled to the power source, a control end coupled to the first gate control circuit for receiving the first gate control signal, and a second end for outputting the power source. The first end of the first switch is coupled to the second end of the first switch when the first switch receives the first gate control signal.

The present invention further provides a power switch for transmitting a power source providing a low voltage between regular mode and deep-power-down mode. The power switch comprises a first gate control circuit and a first switch. The first gate control circuit is disposed for generating a first gate control signal according to a control signal. Voltage of the first gate control signal is higher than the low voltage. The first switch comprises a second end coupled to the power source, a control end coupled to the first gate control circuit for receiving the first gate control signal, and a first end for outputting the power source. The first end of the first switch is coupled to the second end of the first switch when the first switch receives the first gate control signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a conventional power switch for achieving the deep-power-down mode.

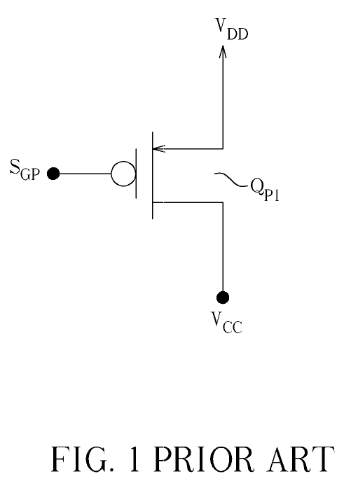

FIG. 2 is a timing diagram illustrating the control signal for the conventional power switch.

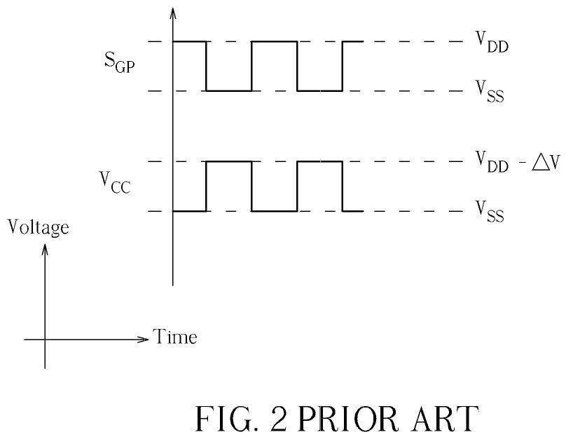

FIG. 3 is a diagram illustrating a power switch according to a first embodiment of the present invention.

FIG. 4 is a timing diagram illustrating the control signal for the power switch according to the first embodiment of the present invention.

FIG. 5 is a diagram illustrating a power switch according to a second embodiment of the present invention.

FIG. 6 is a timing diagram illustrating the control signal for the power switch according to the second embodiment of the present invention.

FIG. 7 is a diagram illustrating a power switch according to a third embodiment of the present invention.

FIG. 8 is a timing diagram illustrating the control signal for the power switch according to the third embodiment of the present invention.

### DETAILED DESCRIPTION

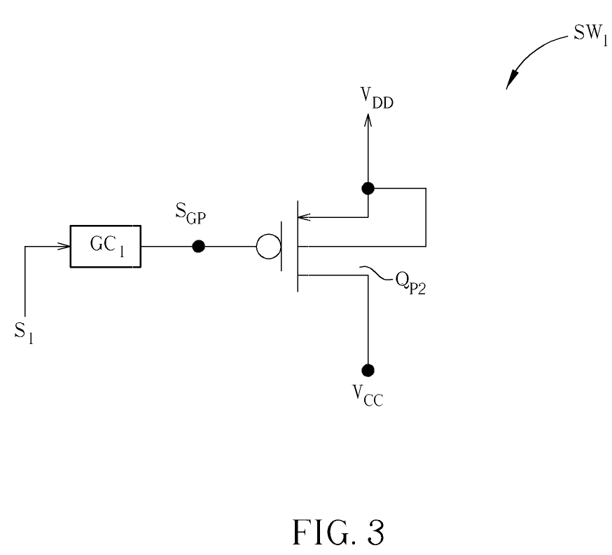

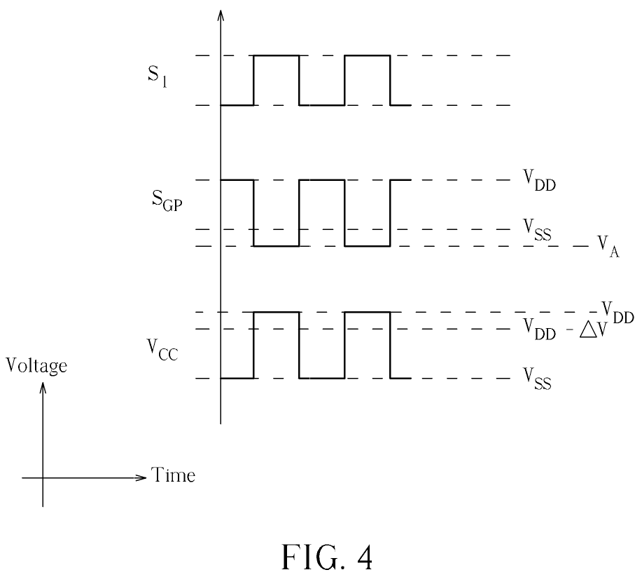

Please refer to FIG. 3 and FIG. 4. FIG. 3 is a diagram illustrating a power switch SW₁ according to a first embodiment of the present invention. FIG. 4 is a timing diagram illustrating the control signal for the power switch SW₁ according to the first embodiment of the present invention. As shown in FIG. 3, the power switch SW₁ comprises a switch Q_{P2} and a gate control circuit GC₁. The switch Q_{P2} is a PMOS transistor. The first end (source) of the switch Q_{P2} is coupled to a main power source V_{DD}, the control end (gate) of the switch Q_{P2} receives a gate control signal S_{GP}, and the second end (drain) of the switch Q_{P2} outputs the power source V_{CC} according to the gate control signal S_{GP}. The gate control circuit GC₁ is coupled to the control end of the switch Q_{P2} for outputting the gate control signal S_{GP} according to a control signal S₁. As shown in FIG. 4, the voltage of the gate control signal S_{GP} falls between the voltage V_{DD} and a voltage V_{A} which is lower than the voltage V_{SS}. When the switch Q_{P2} is to be turned on (the first end of the switch Q_{P2} is coupled to the second of the switch Q_{P2} for outputting the voltage V_{CC}), the control signal S₁ is outputted to the gate control circuit GC₁ so that the voltage of the gate control signal S_{GP} falls to the voltage V_{A} which is below the voltage V_{SS} for completely turning on the switch Q_{P2}; on the other hand, when the switch Q_{P2} is to be turned off (the first end of the switch Q_{P2} is not coupled to the second of the switch Q_{P2} and consequently the voltage V_{CC} is not outputted), the control signal S₁ is not outputted to the gate control circuit GC₁ so that the voltage of the gate control signal S_{GP} rises to the voltage V_{DD}. Since when the switch Q_{P2} is turned on by the gate control signal S_{GP} whose voltage is lower than the voltage V_{SS}, the switch Q_{P2} is turned on completely and the resistance of the switch Q_{P2} is reduced. Consequently the voltage drop on the switch Q_{P2} is reduced and the difference between the voltages V_{DD} and V_{CC} is reduced as well. Therefore, the problem generated by the conventional power switch is solved and the internal chips can still function well. Furthermore, in order to reduce the body effect of the MOS transistor, the body (the third end) of the switch Q_{P2} is coupled to the first end of the switch Q_{P2}. Additionally, the gate control circuit GC₁ can be realized with a charge pump.

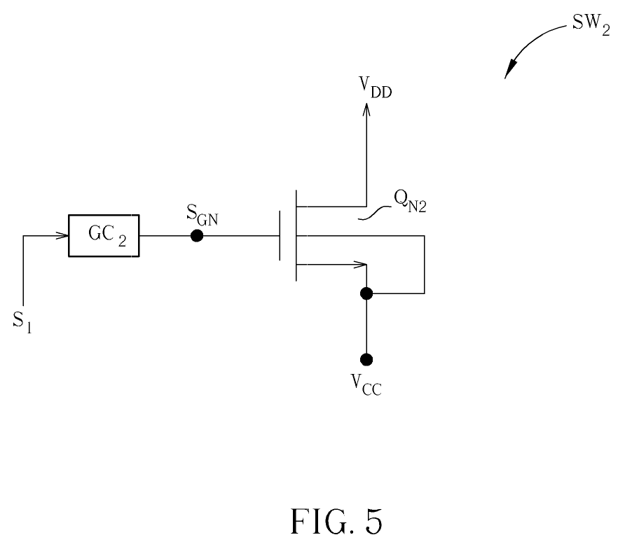

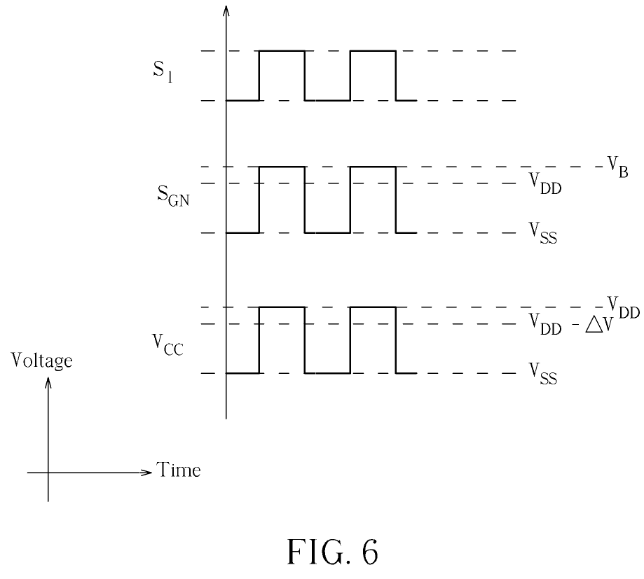

Please refer to FIG. 5 and FIG. 6. FIG. 5 is a diagram illustrating a power switch SW₂ according to a second embodiment of the present invention. FIG. 6 is a timing diagram illustrating the control signal for the power switch SW₂ according to the second embodiment of the present invention. As shown in FIG. 5, the power switch SW₂ comprises a switch Q_{N2} and a gate control circuit GC₂. The switch Q_{N2} is an N channel Metal Oxide Semiconductor (NMOS) transistor. The second end (drain) of the switch Q_{N2} is coupled to a main power source V_{DD}, the control end (gate) of the switch Q_{N2} receives a gate control signal S_{GN}, and the first end (source) of the switch Q_{N2} outputs the power source V_{CC} according to the gate control signal S_{GN}. The gate control circuit GC₂ is coupled to the control end of the switch Q_{N2} for outputting the gate control signal S_{GN} according to a control signal S₁. As shown in FIG. 6, the voltage of the gate control signal S_{GN} falls between the Voltage V_{SS} and a voltage V_{B} which is higher than the voltage V_{DD}. When the switch Q_{N2} is to be turned on (the first end of the switch Q_{N2} is coupled to the second of the switch Q_{N2} for outputting the voltage V_{CC}), the control signal S₁ is outputted to the gate control circuit GC₂ so that the voltage of the gate control signal S_{GN} rises to the voltage V_{B} which is above the voltage V_{DD} for completely turning on the switch Q_{N2}; on the other hand, when the switch Q_{N2} is to be turned off (the first end of the switch Q_{N2} is not coupled to the second of the switch Q_{N2} and consequently the voltage V_{CC} is not outputted), the control signal S₁ is not outputted to the gate control circuit GC₂ so that the voltage of the gate control signal S_{GN} falls to the voltage V_{SS}. Since when the switch Q_{N2} is turned on by the gate control signal S_{GN} whose voltage is higher than the voltage V_{DD}, the switch Q_{N2} is turned on completely and the resistance of the switch Q_{N2} is reduced. Consequently the voltage drop on the switch Q_{N2} is reduced and the difference between the voltages V_{DD} and V_{CC} is reduced as well. Therefore, the problem generated by the conventional power switch is solved and the internal chips can still function well. Furthermore, in order to reduce the body effect of the MOS transistor, the body (the third end) of the switch Q_{N2} is coupled to the first end of the switch Q_{N2}. Additionally, the gate control circuit G_{C2} can be realized with a charge pump.

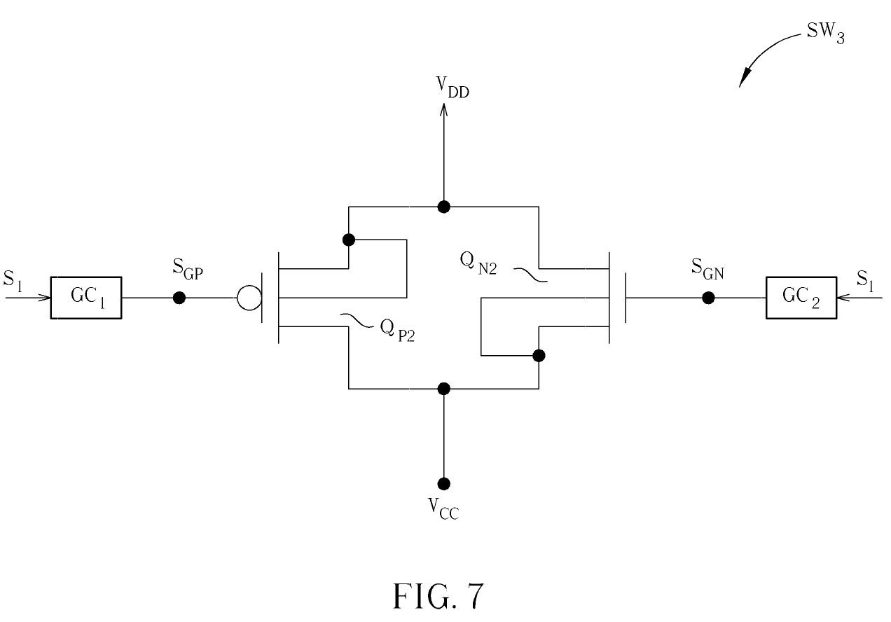

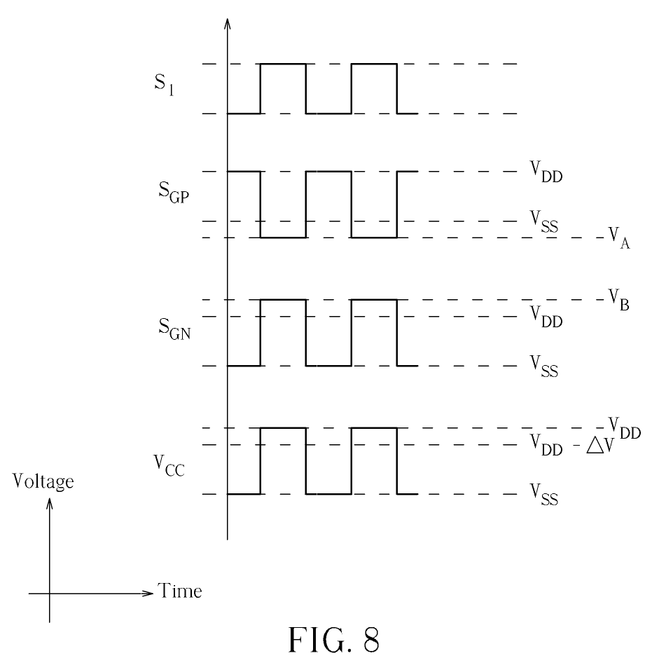

Please refer to FIG. 7 and FIG. 8. FIG. 7 is a diagram illustrating a power switch SW₃ according to a third embodiment of the present invention. FIG. 8 is a timing diagram illustrating the control signal for the power switch SW₃ according to the third embodiment of the present invention. As shown in FIG. 7, the power switch SW₃ comprises two switches Q_{P2} and Q_{N2}, and two gate control circuits GC₁ and GC₂. The switch Q_{P2} is a PMOS transistor, and the switch Q_{N2} is an NMOS transistor. The first end (source) of the switch Q_{P2} is coupled to a main power source V_{DD}, the control end (gate) of the switch Q_{P2} receives a gate control signal S_{GP}, and the second end (drain) of the switch Q_{P2} outputs the power source V_{CC} according to the gate control signal S_{GP}. The second end (drain) of the switch Q_{N2} is coupled to the main power source V_{DD}, the control end (gate) of the switch Q_{N2} receives a gate control signal S_{GN}, and the first end (source) of the switch Q_{N2} outputs the power source V_{CC} according to the gate control signal S_{GN}. The gate control circuits GC₁ and GC₂ are respectively coupled to the control end of the switch Q_{P2} and the control end of the switch Q_{N2} for outputting the gate control signals S_{GP} and S_{GN} according to a control signal S₁. As shown in FIG. 8, the voltage of the gate control signal S_{GP} falls between the voltage V_{DD} and a voltage V_{A} which is lower than the voltage V_{SS}, and the voltage of the gate control signal S_{GN} falls between the voltage V_{SS} and a voltage V_{B} which is higher than the voltage V_{DD}. When the switch Q_{P2} is to be turned on (the first end of the switch Q_{P2} is coupled to the second of the switch Q_{P2} for outputting the voltage V_{CC}) and the switch Q_{N2} is to be turned on (the first end of the switch Q_{N2} is coupled to the second of the switch Q_{N2} for outputting the voltage V_{CC}), the control signal S₁ is outputted to the gate control circuits GC₁ and G_{C2} SO that the voltage of the gate control signal S_{GP} falls to the voltage V_{A} which is below the voltage V_{SS} for completely turning on the switch Q_{P2} and the voltage of the gate control signal S_{GN} rises to the voltage V_{B} which is above the voltage V_{DD} for completely turning on the switch Q_{N2}; on the other hand, when the switch Q_{P2} is to be turned off (the first end of the switch Q_{P2} is not coupled to the second of the switch Q_{P2} and consequently the voltage V_{CC} is not outputted) and the switch Q_{N2} is to be turned off (the first end of the switch Q_{N2} is not coupled to the second of the switch Q_{N2} and consequently the voltage V_{CC} is not outputted), the control signal S₁ is not outputted to the gate control circuits GC₁ and GC₂ so that the voltage of the gate control signal S_{GP} rises to the voltage V_{DD} and the voltage of the gate control signal S_{GN} falls to the voltage V_{SS}. Since when the switch Q_{P2} is turned on by the gate control signal S_{GP} whose voltage is lower than the voltage V_{SS}, and the switch Q_{N2} is turned on by the gate control signal S_{GN} whose voltage is higher than the voltage V_{DD}, the switch Q_{P2} is turned on completely and the resistance of the switch Q_{P2} is reduced, and the switch Q_{N2} is turned on completely and the resistance of the switch Q_{N2} is reduced. Consequently the voltage drop on the switches Q_{P2} and Q_{N2} are reduced and the difference between the voltages V_{DD} and V_{CC} is reduced as well. Therefore, the problem generated by the conventional power switch is solved and the internal chips can still function well. Furthermore, in order to reduce the body effect of the MOS transistor, the body (the third end) of the switch Q_{P2} is coupled to the first end of the switch Q_{P2}, and the body (the third end) of the switch Q_{N2} is coupled to the first end of the switch Q_{N2}. The advantage of the power switch SW₃ is that the outputted power source V_{CC} is still stable when the main power source V_{DD} varies since the switches Q_{P2} and Q_{N2} are complementary to each other.

To sum up, the power switch of the present invention for transmitting power sources of low voltage utilizes gate control circuits to reduce the voltage drop on the power switch. Therefore, when the main power source provides a low voltage, in regular mode, the internal chip power source still provides almost same voltage as the voltage provided from the main power source to the internal chips so as to allow the internal chips to operate normally, and in deep-power-down mode, the internal chip power source can be effectively turned off, providing great convenience.

Those skilled in the art will readily observe that numerous modifications and alterations of the device and method may be made while retaining the teachings of the invention.

What is claimed is:

1. A power switch for transmitting a power source providing a low voltage between regular mode and deep-power-down mode, the power switch comprising:
a first gate control circuit for generating a first gate control signal according to a control signal;
wherein voltage of the first gate control signal is lower than ground; and
a first switch, comprising:
a first end, coupled to the power source;
a control end, coupled to the first gate control circuit for receiving the first gate control signal; and
a second end for outputting the power source;
wherein the first end of the first switch is coupled to the second end of the first switch when the first switch receives the first gate control signal.

2. The power switch of claim 1, wherein the first switch further comprises a third end coupled to the first end of the first switch to eliminate body effect.

3. The power switch of claim 1, wherein the first switch is a P channel Metal Oxide Semiconductor (PMOS) transistor.

4. The power switch of claim 1, further comprising:
a second gate control circuit for generating a second gate control signal according to a control signal;
wherein voltage of the second gate control signal is higher than the low voltage; and
a second switch, comprising:
a second end, coupled to the power source;
a control end, coupled to the second gate control circuit for receiving the second gate control signal; and
a first end for outputting the power source;
wherein the first end of the second switch is coupled to the second end of the second switch when the second switch receives the second gate control signal.

5. The power switch of claim 4, wherein the second switch further comprises a third end coupled to the first end of the second switch to eliminate body effect.

6. The power switch of claim 4, wherein the second switch is an N channel Metal Oxide Semiconductor (NMOS) transistor.

7. The power switch of claim 4, wherein the low voltage is about 1.8 volts or lower.

8. A power switch for transmitting a power source providing a low voltage between regular mode and deep-power-down mode, the power switch comprising:
a first gate control circuit for generating a first gate control signal according to a control signal;
wherein voltage of the first gate control signal is higher than the low voltage; and
a first switch, comprising:
a second end, coupled to the power source;
a control end, coupled to the first gate control circuit for receiving the first gate control signal; and
a first end for outputting the power source;
wherein the first end of the first switch is coupled to the second end of the first switch when the first switch receives the first gate control signal.

9. The power switch of claim 8, wherein the first switch further comprises a third end coupled to the first end of the first switch to eliminate body effect.

10. The power switch of claim 8, wherein the first switch is an N channel Metal Oxide Semiconductor (NMOS) transistor.
